(19) United States
(12) Patent Application Publication
(10) Pub. No.: US 2023/0027528 A1
(43) Pub. Date: Jan. 26, 2023

(54) SEMICONDUCTOR MANUFACTURING METHOD AND SEMICONDUCTOR MANUFACTURING APPARATUS

(71) Applicant: Hitachi High-Tech Corporation, Minato-ku, Tokyo (JP)

(72) Inventors: Yoshihide Yamaguchi, Tokyo (JP); Kiyohiko Sato, Tokyo (JP)

(21) Appl. No.: 17/439,287

(22) PCT Filed: Dec. 10, 2020
(86) PCT No.: PCT/JP2020/046047

§ 371 Date: Sep. 29, 2022

(51) Int. Cl. H01L 21/285; C23C 16/18; C23C 16/52

(52) U.S. Cl. CPC H01L 21/28568; C23C 16/18; C23C 16/52

(57) ABSTRACT

A semiconductor manufacturing method using a semiconductor manufacturing apparatus 100 including a treating chamber 1, the method including: a first process of supplying a complexing gas into the treating chamber in which a wafer 2 having a surface having a transition metal-containing film formed thereon is placed, to adsorb an organic compound as a component of the complexing gas to the transition metal-containing film, the transition metal-containing film containing a transition metal element; and a second process of heating the wafer in which the organic compound is adsorbed to the transition metal-containing film, to react the organic compound with the transition metal element, thereby converting the organic compound into an organometallic complex, and desorbing the organometallic complex, wherein the organic compound has Lewis basicity, and is a multidentate ligand molecule capable of forming a bidentate or more coordination bond with the transition metal element.

### TECHNICAL FIELD

The present invention relates to a semiconductor manufacturing method and a semiconductor manufacturing apparatus for treating a wafer on which a film containing a transition metal element is formed, to manufacture a semiconductor device.

### BACKGROUND ART

The demand for miniaturization, high speed and high performance, and power saving for the most advanced semiconductor devices is accelerating, and various new materials are being adopted. For example, electromigration of Cu (copper) wiring and high resistivity of W (tungsten) wiring become barriers for further miniaturization of semiconductor wiring, and a wide variety of transition metals such as Co (cobalt) and Ru (ruthenium) are candidates for next generation wiring materials. In order to utilize such a conductor film containing a transition metal element as next-generation semiconductor fine wiring, ultra-high-precision processing (film formation and etching) at a nanometer level is essential.

An example of a technique for processing a film structure including a conductor film containing a transition metal element to form a circuit structure of a semiconductor device is a technique disclosed in JP 2008-244039 A (PTL 1). As a lateral etching (trimming) method for using a metal silicide or a metal alone as a gate material, PTL 1 discloses a technique in which the surface of a gate portion is oxidized and then heated while being exposed to a gas containing an organic acid. Furthermore, as described in PTL 1, when Co is oxidized to CoO (cobalt oxide) and then exposed to acetic acid vapor while being heated to 340° C., CoO is converted into volatile Co(CH₃COO)₂ (cobalt acetate) and released into a gas phase.

Meanwhile, JP 2017-59824 A (PTL 2) discloses a technique in which a pretreating gas selected from a mixed gas of a halogen-containing substance and NO (nitrogen monoxide) and nitrosyl fluoride (NOF) or the like is reacted with a material containing a noble metal element such as Pt to form a solid compound on the surface, and the solid compound is then reacted with β-diketone, followed by etching. PTL 2 describes that a solid compound produced by reacting NOFx (x=1 to 3) produced in a reaction vessel from NOF contained in the pretreating gas or a component of the pretreating gas with the material containing a noble metal such as Pt at 50° C. or higher and 150° C. or lower is a Pt compound containing Pt, N, O, and F. The Pt compound is reacted with β-diketone to produce a complex of highly volatile β-diketone and Pt, and the complex is vaporized. The noble metals exemplified in PTL 2 are Au, Pt, Pd, Rh, Ir, Ru, and Os, and are all classified as transition metals.

### CITATION LIST

### Patent Literature

PTL 1: JP 2008-244039 A

PTL 2: JP 2017-59824 A

### SUMMARY OF INVENTION

### Technical Problem

In the course of examining a technique of ultra-high-definition processing at a nanometer level of materials containing a wide variety of transition metal elements, the inventors have studied and verified a technique of highly accurately processing a multilayer film in which different several tens of materials are laminated. The technique is particularly found in the most advanced three-dimensional devices. In this study, the inventors have found that the multilayer film in which different materials are laminated in a multiple manner is heated to a high temperature, which causes defects such as diffusion of the different materials between films or shift in position between the multilayer film due to the different materials and thus films having different expansion coefficients being laminated. For this reason, the inventors have found that an etching technique which can be performed at a relatively low temperature is required for processing the multilayer film in which different materials are laminated in a multiple manner.

The techniques disclosed in PTL 1 and PTL 2 are promising techniques from the above findings because selective etching can be achieved at 400° C. or lower. However, as a result of detailed verification of these conventional techniques, the inventors have found that the techniques have problems to be improved, as follows.

In the technique disclosed in PTL 1, an acetate of a transition metal has volatility, but is not necessarily stable at a high temperature. More specifically, cobalt acetate is known to be thermally decomposed at about 220° C. or higher. That is, a reaction mechanism in which cobalt oxide is converted into cobalt acetate by exposing the cobalt oxide heated at 340° C. to acetic acid vapor, and the cobalt acetate is then volatilized and removed causes the etching of the cobalt oxide to proceed. Meanwhile, the cobalt acetate which is an intermediate product of the etching reaction causes an abnormal reaction such as thermal decomposition to produce a residue containing Co and C.

As a result, fine particles of a residue obtained by decomposition of the cobalt acetate are attached to at least a part of the surface of the cobalt oxide film. In the film to be treated immediately below a region to which the fine particles of the residue are attached, etching is inhibited or the progress of the etching process is stopped. Meanwhile, in a region to which the fine particles of the residue are not attached, etching relatively proceeds. As a result, bumpy and uneven occur in the surface of the film to be treated after the completion of the etching treatment according to the attached amount of the particles of the residue. Since the bumpy and uneven cause large variations in the shape after processing with respect to the in-plane direction of the surface of the wafer, fine processing accuracy required in terms of the performance of the semiconductor device cannot be obtained, so that the yield and efficiency of the treatment are reduced.

According to the study of the inventors, when the technique disclosed in Patent Document 2 is applied to a transition metal element which is not a noble metal element, for example, Zr (zirconium) or the like, a highly volatile complex is produced in an amount less than or equal to the detection limit, which makes it difficult to obtain a practical etching rate. Zr is reacted with NOF to produce ZrF₄ (zirconium fluoride) which is a solid compound containing no N and O. ZrF₄ has lower reactivity with β-diketone than that of a solid compound containing N and O obtained by the reaction of Pt and NOF. Therefore, the reaction for producing a volatile substance does not sufficiently proceed. Therefore, the technique cannot be applied to the etching treatment of a film containing a transition metal element other than a noble metal, and applicable materials are limited.

An object of the present invention is to provide a semiconductor manufacturing method or a semiconductor manufacturing apparatus which treats a film containing a transition metal element with high processing accuracy and at a high speed to provide improved manufacturing efficiency and yield of a semiconductor device.

### Solution to Problem

A semiconductor manufacturing method according to an embodiment of the present invention is a semiconductor manufacturing method using a semiconductor manufacturing apparatus including a treating chamber, the method including: a first step of supplying a complexing gas into the treating chamber in which a wafer having a surface having a transition metal-containing film formed thereon is placed, to adsorb an organic compound as a component of the complexing gas to the transition metal-containing film, the transition metal-containing film containing a transition metal element; and a second step of heating the wafer in which the organic compound is adsorbed to the transition metal-containing film, to react the organic compound with the transition metal element, thereby converting the organic compound into an organometallic complex, and desorbing the organometallic complex, wherein the organic compound has Lewis basicity, and is a multidentate ligand molecule capable of forming a bidentate or more coordination bond with the transition metal element.

A semiconductor manufacturing apparatus according to an embodiment of the present invention includes: a chamber in which a treating chamber is provided; a wafer stage which is disposed in the treating chamber and on which a wafer having a surface having a transition metal-containing film formed thereon is placed, the transition metal-containing film containing a transition metal element; a complexing gas feeder which includes a tank storing a chemical liquid containing an organic compound as a component, and supplies an organic gas obtained by vaporizing the chemical liquid to the treating chamber as a complexing gas; a heater heating the wafer; and a control unit, wherein: the control unit executes a first step of supplying the complexing gas from the complexing gas feeder into the treating chamber in which the wafer is placed, to adsorb an organic compound as a component of the complexing gas to the transition metal-containing film, and a second step of causing the heater to heat the wafer in which the organic compound is adsorbed to the transition metal-containing film to react the organic compound with the transition metal element, thereby converting the organic compound into an organometallic complex, and desorbing the organometallic complex; and the organic compound has Lewis basicity, and is a multidentate ligand molecule capable of forming a bidentate or more coordination bond with the transition metal element.

### Advantageous Effects of Invention

An etching treatment is achieved while the roughness of the surface of a film containing a transition metal is suppressed.

Other problems and novel features will be apparent from the description of the present specification and the accompanying drawings.

### BRIEF DESCRIPTION OF DRAWINGS

FIG. 1 is a diagram schematically showing the overall configuration of a semiconductor manufacturing apparatus.

FIG. 2 is a flowchart of a treatment for etching a film to be treated.

FIG. 3 is a time chart schematically showing the flow of an operation with respect to the time of an etching treatment.

FIG. 4 is a time chart schematically showing the flow of an operation with respect to the time of an etching treatment.

FIG. 5 is a time chart schematically showing the flow of an operation with respect to the time of an etching treatment.

### DESCRIPTION OF EMBODIMENTS

The inventors verified and reexamined a reaction mechanism while etching of a film containing a transition metal proceeds from various viewpoints, and found a phenomenon that when the valence of a transition metal element is controlled, and a film to be treated is exposed to an organic gas containing a Lewis base having a specific molecular structure, an organometallic complex having high thermal stability and high volatility can be produced. The present invention utilizes this phenomenon to achieve highly efficient etching.

The Lewis base has unshared electron pairs which can be donated in its molecule by definition. The Lewis base donates the unshared electron pairs to positive charges of the transition metal element of the film to be treated, to form an electron-donating +back-donating type strong coordination bond, thereby forming a thermally stable organometallic complex (complex compound). Inside the produced organometallic complex, the positive charges of the metal element of the film to be treated are neutralized in a charge manner by the unshared electron pairs donated from the Lewis base contained in the organic gas. Thus, charge neutralization causes an electrostatic attractive force acting between adjacent molecules to disappear, which can provide enhanced volatility (sublimability).

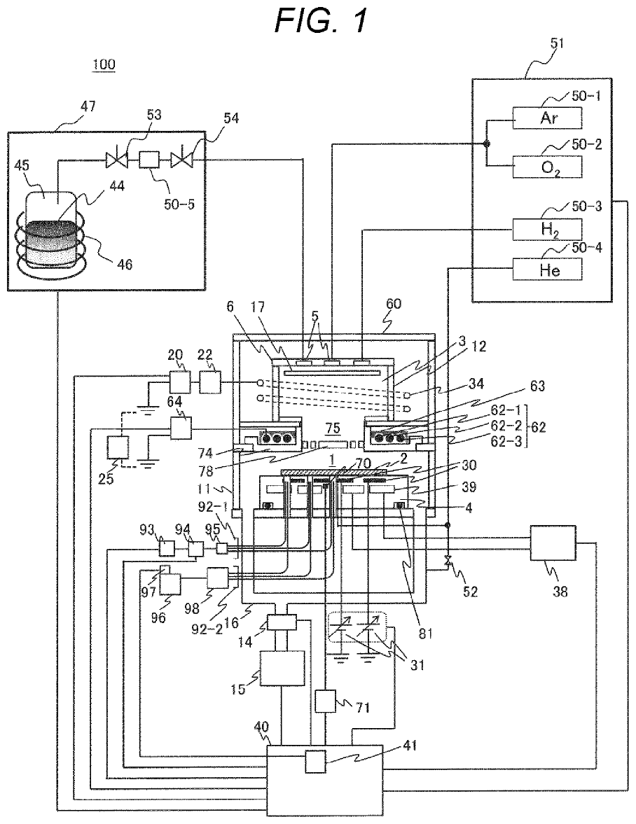

Hereinafter, an embodiment of the present invention will be described with reference to FIG. 1 to FIG. 5. Note that, in the present specification and the drawings, components having substantially the same function are denoted by the same reference numerals, and redundant description will be omitted.

FIG. 1 is a longitudinal sectional view schematically showing the overall configuration of a semiconductor manufacturing apparatus.

A treating chamber 1 is constituted by a base chamber 11 which is a cylindrical metal container, and a wafer stage 4 (hereinafter, referred to as a stage 4) for placing a wafer 2 which is a sample to be treated is installed therein. An inductively coupled plasma (ICP) discharge system is used as a plasma source, and a quartz chamber 12, and a plasma source including an ICP coil 34 and a radio frequency power source 20 are installed above the treating chamber 1. The ICP coil 34 is installed outside the quartz chamber 12.

The radio frequency power supply 20 for plasma production is connected to the ICP coil 34 via a matching device 22. A frequency band of several tens of MHz such as 13.56 MHz is used as the frequency of radio frequency power. A top plate 6 is installed above the quartz chamber 12. A shower plate 5 is installed on the top plate 6, and a gas dispersion plate 17 is installed below the shower plate 5. A gas (treating gas) supplied into the treating chamber 1 for processing the wafer 2 is introduced into the treating chamber 1 from the outer periphery of the gas dispersion plate 17.

The flow rate of the treating gas to be supplied is adjusted by mass flow controllers 50 disposed in an integrated mass flow controller control unit 51 and installed for gas types. In the example of FIG. 1, at least Ar, O₂, and H₂ are supplied to the treating chamber 1 as treating gases, and mass flow controllers 50-1, 50-2, and 50-3 are provided to respectively correspond to the gas types. The gases to be supplied are not limited thereto. In the integrated mass flow controller control unit 51, a mass flow controller 50-4 is also disposed, which adjusts the flow rate of a He gas supplied between the back surface of the wafer 2 and the upper surface of a dielectric film of the stage 4 on which the wafer 2 is placed as described later.

In the present Example, a complexing gas produced from a liquid raw material is used as at least a part of the treating gas. The complexing gas is obtained by vaporizing a liquid raw material by a complexing gas feeder 47. In the complexing gas feeder 47, a tank 45 which stores a chemical liquid 44 as a liquid raw material is provided. The chemical liquid 44 is heated by a heater 46 covering the periphery of the tank 45. The upper portion of the tank 45 is filled with raw material vapor. The chemical liquid 44 is a raw material liquid of a complexing gas as a component for converting a film containing a transition metal element (hereinafter, referred to as a transition metal-containing film) and formed in advance on the wafer 2 into a volatile organometallic complex. The produced raw material vapor is introduced at a predetermined flow rate and speed under the control of the flow rate by a mass flow controller 50-5, thereby becoming a gas having a desired concentration suitable for treating in the treating chamber 1. While the raw material vapor is not introduced into the treating chamber 1, valves 53 and 54 are closed to block the liquid raw material from the treating chamber 1. Furthermore, a pipe through which the raw material vapor flows is desirably heated so that the raw material vapor does not condense in the pipe.

In order to decompress the treating chamber 1, the lower portion of the treating chamber 1 is connected to an exhaust mechanism 15 by a vacuum exhaust pipe 16. The exhaust mechanism 15 is configured by, for example, a turbo molecular pump, a mechanical booster pump, or a dry pump. In order to adjust a pressure in the treating chamber 1 or a discharge region 3, the flow rate of an internal gas or plasma particles discharged from the inside of the treating chamber 1 is adjusted by increasing or decreasing the flow path cross-sectional area of the vacuum exhaust pipe 16 (cross-sectional area on a plane perpendicular to the axial direction of the vacuum exhaust pipe 16). Therefore, a pressure regulation mechanism 14 including a plurality of plate-shaped flaps whose axes are disposed in a direction crossing the inside of the flow path and which rotate around the axes and a plate member which moves inside the flow path across the axial direction is installed on the upstream side of the exhaust mechanism 15.

An infrared (IR) lamp unit for heating the wafer 2 is installed between the stage 4 and the quartz chamber 12 constituting the ICP plasma source. The IR lamp unit includes an IR lamp 62 disposed in a ring shape above the upper surface of the stage 4, a reflector 63 disposed above the IR lamp 62 so as to cover the IR lamp 62 and reflecting IR light, and an IR light transmission window 74. As the IR lamp 62, multiple circular lamps concentrically or spirally disposed around the vertical central axis of the base chamber 11 or the cylindrical stage 4 are used. Light emitted from the IR lamp 62 mainly includes infrared light from visible light. Herein, such light is referred to as IR light. In the configuration example shown in FIG. 1, three turns of IR lamps 6-1, 62-2, and 62-3 are installed as the IR lamp 62, but two, four, or other number of turns of lamps may be installed.

An IR lamp power supply 64 is connected to the IR lamp 62, and a radio frequency cut filter 25 is installed to prevent noise from radio frequency power for plasma production generated by the radio frequency power supply 20 from flowing into the IR lamp power supply 64. The IR lamp power supply 64 has a function of being capable of controlling the power supplied to the IR lamps 62-1, 62-2, and 62-3 independently of each other, and can adjust the radial distribution of the heating amount of the wafer 2.

A gas flow path 75 is formed at the center of the IR lamp unit. The gas flow path 75 allows a gas supplied from the mass flow controller 50 into the quartz chamber 12 to flow into the treating chamber 1. In the gas flow path 75, a slit plate (ion shielding plate) 78 is disposed. The slit plate shields ions and electrons produced in the plasma generated in the quartz chamber 12, and has a plurality of holes for allowing only neutral gas and neutral radicals to pass therethrough to irradiate the wafer 2 with the gas and the radicals.

A refrigerant flow path 39 for cooling the stage 4 is formed in the stage 4, and the refrigerant is supplied in circulation by a chiller 38. In order to fix the wafer 2 to the stage 4 by electrostatic adsorption, electrostatic adsorption electrodes 30 which are plate-like electrode plates are embedded in the stage 4, and a direct current (DC) power supply 31 for electrostatic adsorption is connected to each of the electrostatic adsorption electrodes.

In order to efficiently cool the wafer 2, a He gas is supplied between the back surface of the wafer 2 placed on the stage 4 and the upper surface of the stage 4. The He gas is supplied through a supply path in which an on-off valve 52 is disposed, and a flow rate and a speed thereof are appropriately adjusted by the mass flow controller 50-4. The He gas is introduced into a clearance between the back surface of the wafer 2 and the upper surface of the stage 4 from an opening disposed in the upper surface of the stage 4 on which the wafer 2 is placed through a passage in the stage 4 connected in communication with the supply path. As a result, heat transfer between the wafer 2 and the stage 4 and the refrigerant flowing through the internal flow path 39 is promoted.

The wafer placement surface of the stage 4 is coated with a resin such as polyimide in order to prevent the back surface of the wafer 2 from being scratched even when the wafer 2 is heated or cooled while the wafer 2 is electrostatically adsorbed by operating the electrostatic adsorption electrode 30.

A thermocouple 70 is installed in the stage 4 to measure the temperature of the stage 4, and the thermocouple is connected to a thermocouple thermometer 71. Furthermore, optical fibers 92-1 and 92-2 for measuring the temperature of the wafer 2 are respectively installed at three locations: near the center portion of the wafer 2, near a radially middle location of the wafer 2, and near the outer periphery of the wafer 2. The optical fiber 92-1 guides IR light from an external IR light source 93 to the back surface of the wafer 2 to irradiate the back surface of the wafer 2 with the IR light. Meanwhile, the optical fiber 92-2 collects the IR light absorbed and reflected by the wafer 2 among the IR light irradiated by the optical fiber 92-1, and transmits the IR light to a spectroscope 96.

Specifically, the external IR light produced by the external IR light source 93 is transmitted to an optical path switch 94 for opening and closing the optical path. The external IR light is then split into multiple (three in this example) beams by a light splitter 95, and the resultant beams irradiate each position on the back surface side of the wafer 2 through the three optical fibers 92-1. The IR light absorbed and reflected by the wafer 2 is transmitted to the spectroscope 96 by the optical fiber 92-2, and data of dependence of spectral intensity on wavelength is obtained by a detector 97. The resulting data of dependence of spectral intensity on wavelength is sent to a calculation unit 41 of a control unit 40, to calculate an absorption wavelength, and the temperature of the wafer 2 can be obtained based on the absorption wavelength. An optical multiplexer 98 is installed on the optical fiber 92-2, and performs switching to select which light is to be spectroscopically measured from the light at measurement points: the center of the wafer, the middle of the wafer, and the outer periphery of the wafer. As a result, the calculation unit 41 can obtain the temperature of each of the center of the wafer, the middle of the wafer, and the outer periphery of the wafer.

In FIG. 1, reference numeral 60 denotes a container which covers the quartz chamber 12, and reference numeral 81 denotes an O-ring for vacuum-sealing between the stage 4 and the bottom surface of the base chamber 11.

The control unit 40 controls on/off of radio frequency power supply from the radio frequency power source 20 to the ICP coil 34. The integrated mass flow controller control unit 51 is controlled to adjust the type and flow rate of the gas supplied from each mass flow controller 50 into the quartz chamber 12. In this state, the control unit 40 operates the exhaust mechanism 15 and controls the pressure regulation mechanism 14 to adjust the inside of the treating chamber 1 to have a desired pressure.

Furthermore, the control unit 40 controls the IR lamp power supply 64 and the chiller 38 so that the temperature of the wafer 2 falls within a predetermined temperature range on the basis of the temperature inside the stage 4 measured by the thermocouple thermometer 71 and/or the temperature distribution information of the wafer 2 obtained by the calculation unit 41 on the basis of spectrum intensity information near the center portion, the radial middle portion, and the outer periphery of the wafer 2 measured by the detector 97 in a state where the DC power supply 31 for electrostatic adsorption is operated to electrostatically adsorb the wafer 2 to the stage 4 and the mass flow controller 50-4 which supplies the He gas between the wafer 2 and the stage 4 is operated.

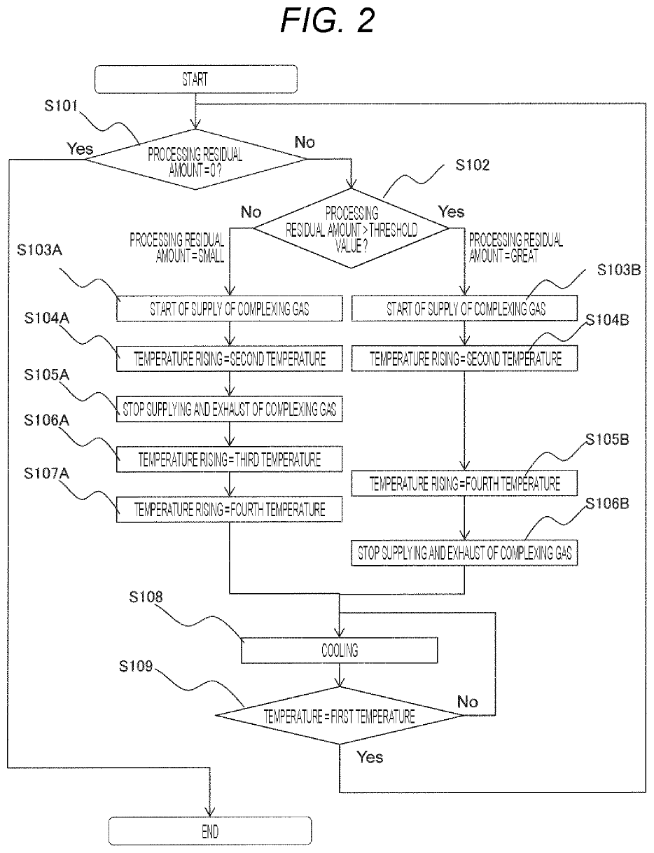

Next, a flow in which the semiconductor manufacturing apparatus of the present Example treats the wafer 2 will be described with reference to FIG. 2 to FIG. 4. FIG. 2 is a flowchart of a treatment in which the semiconductor manufacturing apparatus shown in FIG. 1 etches a film to be treated formed on a wafer. The film to be treated is a transition metal-containing film. Operations such as introduction of the treating gas into the treating chamber 1, exhaust, and heating of the wafer 2 by irradiation of the IR light by the IR lamp 62, which are performed in each step of a semiconductor manufacturing apparatus 100 related to the etching treatment, are controlled by the control unit 40.

A vacuum transfer container, which is another vacuum container, is connected to a side wall of the base chamber 11. A transfer robot including a plurality of arms is disposed in the vacuum transfer container. The wafer 2 is held on a hand at the distal end of the arm, transferred in the transfer space of the vacuum transfer container, and introduced into the treating chamber 1 through the gate of the base chamber 11. A dielectric film containing aluminum oxide or yttrium oxide is disposed on an upper surface constituting the placement surface of the wafer 2 of the stage 4. The wafer 2 is held on the dielectric film of the stage 4, and is adsorbed and fixed by the gripping force of the upper surface of the film due to an electrostatic force generated by DC power supplied to the film made of metal such as tungsten disposed in the dielectric film.

A stacked film structure including a transition metal-containing film processed in advance into a pattern shape constituting a circuit structure of a semiconductor device is formed on the upper surface of the wafer 2, and a part of the surface of the film to be treated (transition metal-containing film) is exposed.

Examples of the transition metal-containing film include lanthanum oxide (La₂O₃), cobalt, copper, tungsten, titanium, and hafnium oxide, but are not limited to the film containing the transition metal element exemplified herein. The film structure including the film to be treated is formed so as to have a film thickness with which a desired circuit can be configured using a known sputtering method, a physical vapor deposition (PVD) method, an atomic layer deposition (ALD) method, or a chemical vapor deposition (CVD) method, or the like. The film structure may be processed using a photolithography technique so as to have a shape conforming to a circuit pattern.

The semiconductor manufacturing apparatus 100 removes the transition metal-containing film to be treated exposed on the surface by selective etching. In this selective etching, a dry etching technique not using plasma as described later is applied. Before the etching treatment, an oxidation or reduction treatment may be performed in order to adjust the valence of the transition metal element of the transition metal-containing film. This is because, depending on the valence of the transition metal element, the transition metal element is not bonded to the complexing gas to form the organometallic complex. Therefore, the transition metal-containing film to be treated in the present Example may be an oxide film or a metal film. In any film, the etching treatment of the present Example can be applied by performing the oxidation or reduction treatment to control the transition metal element in the film to an appropriate valence in the etching treatment. The treatment of adjusting the valence of the transition metal element may be executed every cycle of the etching treatment to be described later depending on the film thickness to be subjected to the etching treatment.

In a state where the wafer 2 is held on the stage 4, a He gas whose the flow rate or speed is adjusted by the mass flow controller 50-4 is introduced into the clearance between the wafer 2 and the stage 4 from the opening in the upper surface of the stage 4, and heat transfer therebetween is promoted to adjust the temperature of the wafer 2. When the fact that the temperature (hereinafter, referred to as a substrate temperature) of the wafer 2 has reached the first temperature T₁ or lower (cooled in the present example) is detected by the control unit 40, the etching treatment of the transition metal-containing film to be treated is started. The control unit 40 may measure the temperature of the wafer 2 by spectroscopic measurement using the optical fiber 92 to obtain a substrate temperature, or may estimate the substrate temperature from the temperature of the stage 4 measured by the thermocouple thermometer 71.

Step S101 is a step of determining a remaining film thickness to be etched for the transition metal-containing film to be treated formed on the surface of the wafer 2. In the present step, in both the case where the etching treatment is performed for the first time after the wafer 2 is loaded and the case where the etching treatment has already been performed, the remaining film thickness (hereinafter, referred to as a processing residual amount) of the film to be treated is calculated by the control unit 40 with appropriate reference to the design and specification values of the semiconductor device to be manufactured. The calculation unit 41 of the control unit 40 reads software stored in a storage device of the control unit 40, calculates a value of an accumulated amount of processing (accumulated processing amount) by the treatment performed on the wafer 2 before being loaded into the treating chamber 1 and an accumulated amount of processing by the treatment performed after being loaded into the treating chamber 1 according to the algorithm, and determines whether or not additional processing is necessary on the basis of the design and specification values of the wafer 2.

When the processing residual amount is 0, or sufficiently small to be regarded as 0, and is determined to be smaller than a predetermined allowable value 50, the etching treatment of the film to be treated is completed. Meanwhile, when that the processing residual amount is determined to be not 0 (or is equal to or greater than the allowable value 50), the process proceeds to step S102. In step S102, it is determined whether the processing residual amount is more or less (greater or smaller) than a predetermined threshold value. In the case where the processing residual amount is determined to be more than the threshold value, the process proceeds to step S103B, and in the case where the processing residual amount is determined to be less than the threshold value, the process proceeds to step S103A.

The accumulated processing amount as a result of performing the treatment shown in FIG. 2 on the wafer 2 transferred to the treating chamber 1 once or more in the semiconductor manufacturing apparatus 100 can be simply obtained from the accumulated number of treatment cycles of a group of steps S102 to S109 and the processing amount (processing rate) per treatment cycle acquired in advance. The processing amount may be calculated by surface analysis of the wafer 2, an output from a detector of a remaining film thickness (not shown), or a combination thereof.

In the case where the processing residual amount is determined to be greater than the predetermined threshold value in step S102, the process proceeds to step S103B, and the process up to step S106B (process B) are performed. Meanwhile, when the processing residual amount is determined to be equal to or less than the predetermined threshold value in step S102, the process proceeds to step S103A, and the process up to step S107A (process A) are performed. By the process A or the process B, the etching treatment of the film to be treated is performed, and the remaining film thickness is reduced.

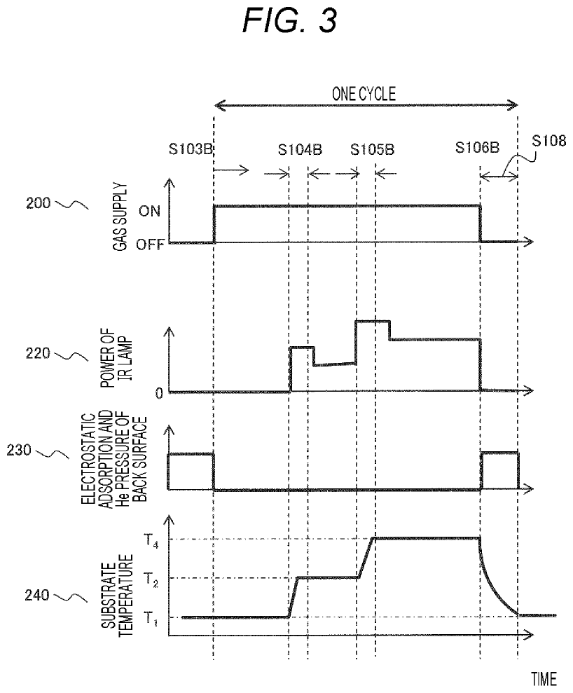

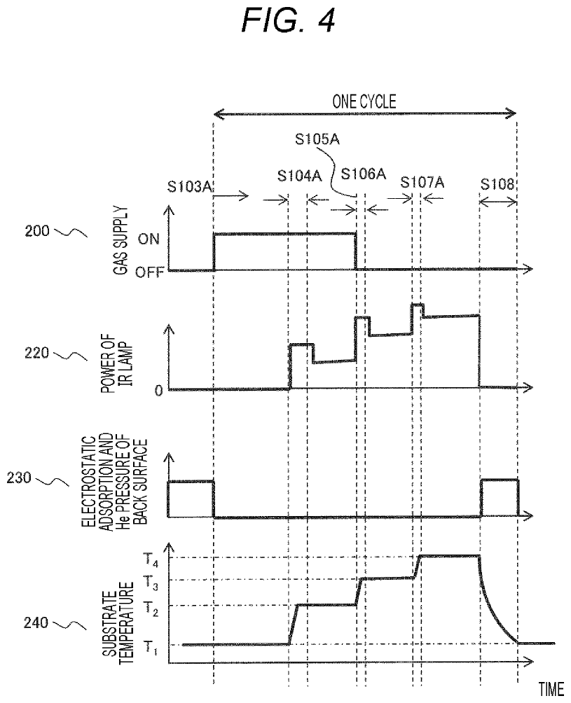

Hereinafter, a flow of a treatment of etching the transition metal-containing film by the semiconductor manufacturing apparatus 100 will be described with reference to FIG. 3 or 4 together with FIG. 2. FIG. 3 and FIG. 4 are time charts schematically showing the flow of the operation with respect to the transition of time of the etching treatment of the transition metal-containing film to be treated on the wafer performed by the semiconductor manufacturing apparatus. FIG. 3 shows a time chart of a process B performed in the case of “processing residual amount>threshold value” (step S102), and FIG. 4 shows a time chart of a process A performed in the case of “processing residual amount<threshold value” (step S102). FIG. 3 and FIG. 4 schematically show the operations of heating and cooling of the wafer 2, gas supply, and exhaust during the etching treatment, and the actually realized temperature, temperature gradient, and necessary control time differ depending on the material to be etched (transition metal-containing film), the type of the complexing material (organic compound), and the structure of the semiconductor device, and the like.

When the determination result in step S102 is “processing residual amount>threshold value”, the process proceeds to step S103B, and the supply of the complexing gas into the treating chamber 1 is started. The complexing gas is a gas containing an organic substance for converting the transition metal-containing film into a volatile organometallic complex, and the vapor of the chemical liquid 44 stored in the tank 45 is supplied by the complexing gas supply mass flow controller 50-5 so that the flow rate or the speed is adjusted to a value within a range suitable for treating. The supply conditions (supply amount, supply pressure, supply time, and gas temperature and the like) of the complexing gas and the type of the complexing gas are determined in consideration of the element composition, shape, and film thickness of the transition metal-containing film, and the boiling point of the complexing gas. The control unit 40 selects a supply condition in accordance with an algorithm described in software stored in the storage device, and transmits a command signal corresponding to the supply condition to each mechanism.

Step S103B is a step of forming a physical adsorption layer of the particles of the complexing gas on the surface of the transition metal-containing film to be treated. This step is performed while the substrate temperature is maintained in a temperature range equal to or lower than the boiling point of the complexing gas (first temperature T₁ in FIG. 3). The present step is completed when the minimum number of physical adsorption layers to be etched in one process is formed. This number of layers is selected in consideration of desired processing accuracy and processing amount. Since the physical adsorption layer to be formed is mainly determined by the surface state and temperature of the film to be treated and the pressure of the gas, the process proceeds to step S104B when a predetermined time has elapsed according to the supply condition.

In step S104B, while the supply of the complexing gas is continued, power is supplied from the IR lamp power supply 64 to the IR lamp 62 to emit IR light. The wafer 2 is heated by the IR light, to cause the substrate temperature to rapidly rise to a second temperature T₂. During a period in which the wafer 2 is heated to and maintained at the second temperature T₂ higher than the first temperature T₁, the reactivity of the material of the transition metal-containing film is activated, and the state of adsorption of the particles of the complexing gas to the film changes from physical adsorption to chemical adsorption.

In the next step S105B, while the supply of the complexing gas is continued, the wafer 2 is further heated by the IR lamp 62, to raise the substrate temperature to a fourth temperature T₄ higher than the second temperature T₂. When the temperature of the wafer 2 is raised and activation energy is applied to the particles of the complexing gas chemically adsorbed to the film, the conversion of the film into an organometallic complex is started. During a period in which the wafer 2 is heated to and maintained at the fourth temperature T₄ higher than the second temperature T₂, (1) a first phenomenon in which the organometallic complex produced on the surface of the transition metal-containing film is volatilized, and desorbed and removed from the film surface, and (2) a second phenomenon in which the continuously supplied complexing gas is reacted with the transition metal-containing film to be converted into a volatile organometallic complex proceed in parallel. When a specific small region on the surface of the film to be treated during this period is microscopically viewed, on the surface of the film in the region, the phenomenon proceeds intermittently or in a stepwise fashion between the removal of the complex on the surface of the film by volatilization (desorption) and the conversion and formation of a new complex in the order of (1) (2) (1) (2) . However, when the film to be treated is viewed as a whole, it can be understood that substantially continuous etching proceeds.

By supplying the complexing gas to the wafer 2 during a predetermined period and maintaining the substrate temperature at the fourth temperature T₄, substantially continuous etching is continued, and after the etching amount reaches a desired amount, the process proceeds to step S106B to stop the supply of the complexing gas. Meanwhile, the inside of the treating chamber 1 is continuously exhausted through the vacuum exhaust pipe 16 by the exhaust mechanism 15, and the exhaust is continuously performed even in a plurality of processes including the stop of the supply of the complexing gas and the cooling (S108) of the wafer 2 in step S106B, whereby the gas and the product particles in the treating chamber 1 are exhausted to the outside of the treating chamber 1.

Meanwhile, when the determination result in step S102 is “processing residual amount<threshold value”, the process proceeds to step S103A, and the supply of the complexing gas into the treating chamber 1 is started. After the required minimum number of physical adsorption layers is formed in step S103A, the process proceeds to step S104A, and the substrate temperature is rapidly raised to the second temperature T₂ by heating the wafer 2 by irradiation with IR light from the IR lamp 62.

Similarly to the process B, also in the process A, the supply condition of the complexing gas and the type of the complexing gas are determined in consideration of the element composition, shape, and film thickness of the transition metal-containing film, and the boiling point of the complexing gas. The control unit 40 selects the supply condition in accordance with the algorithm described in the software stored in the storage device, and transmits a command signal corresponding to the supply condition to each mechanism. During the period in which the wafer 2 is heated to and maintained at the second temperature T₂ higher than the first temperature T₁, the reactivity of the material of the surface of the transition metal-containing film is activated, and the state of adsorption of the particles of the complexing gas to the film surface changes from physical adsorption to chemical adsorption as in the case of the process B.

In a state where the complexing gas is chemically adsorbed to the transition metal-containing film, the molecules of the complexing gas and the transition metal atom contained in the transition metal-containing film are firmly fixed by a chemical bond. In other words, the complexing gas molecules can be said to be “pinned” to the surface of the transition metal-containing film, as a result of which the diffusion rate of the chemically adsorbed complexing gas molecules is slow.

In the next step S105A, the supply of the complexing gas is stopped, and the inside of the treating chamber 1 is exhausted. The inside of the treating chamber 1 is exhausted to leave the complexing gas chemically adsorbed to the transition metal-containing film, and the complexing gas in the non-adsorbed state or the physical adsorption state is wholly exhausted and removed to the outside of the treating chamber 1.

Next, the irradiation amount of IR light from the IR lamp 62 with which the wafer 2 is continuously irradiated from step S104A is increased by the command signal from the control unit 40, to raise the substrate temperature to a third temperature T₃ (step S106A). Then, the wafer 2 is maintained at the third temperature T₃ only during a predetermined period. During the period in which the wafer 2 is heated to and maintained at the third temperature T₃, the particles of the complexing gas chemically adsorbed to the surface of the transition metal-containing film are gradually converted into the volatile organometallic complex by the reaction with the material of the film surface. At this time, since no complexing gas other than the complexing gas fixed by chemical adsorption is present in the treating chamber 1, the thickness of the produced organometallic complex layer is equal to or less than the thickness of a chemical adsorption layer.

Then, the irradiation amount of the IR light from the IR lamp 62 is further increased, to raise the substrate temperature to the fourth temperature T₄ (step S107A). Then, the wafer 2 is maintained at the fourth temperature T₄ only during a predetermined period. During a period in which the wafer 2 is heated to and maintained at the fourth temperature T₄, the organometallic complex formed on the film surface is desorbed, and removed from the surface of the film to be treated.

The process A constituted by the series of steps of step S103A-step S104A-step S105A-step S106A-step S107A and the process B constituted by the series of steps of step S103B-step S104B-step S105B-step S106B, as described above, are the same until the chemical adsorption layer is produced on the surface of the transition metal-containing film of the wafer 2, but have different operation flows after the subsequent step in which the chemical adsorption layer is converted into the organometallic complex.

In the process A, during a period in which the substrate temperature is raised to and maintained at the fourth temperature T₄ in a state where the supply of the complexing gas is stopped, desorption of about one to several layers of the organometallic complex converted from the chemical adsorption layer is completed, and the transition metal-containing film immediately therebelow is exposed, whereby the reaction is terminated. Meanwhile, in the process B, the substrate temperature is raised to and maintained at the fourth temperature T₄ while the supply of the complexing gas is continued, whereby even if the desorption of about one to several layers of the organometallic complex converted from the chemical adsorption layer is completed and the unreacted transition metal-containing film immediately therebelow is exposed, the exposed film is heated to the fourth temperature T₄ to increase the activity degree thereof. Therefore, when the complexing gas and the transition metal-containing film come into contact with each other, the processes of physical adsorption, chemical adsorption, and complex conversion proceed at once, to cause the conversion of the complexing gas into the organometallic complex to occur immediately after the contact of the complexing gas. Furthermore, the produced organometallic complex is quickly desorbed, whereby continuous etching of the film to be treated proceeds as a whole.

Therefore, in the etching treatment during the period in which the substrate temperature in the process B is raised to and maintained at the fourth temperature T₄, a phenomenon is exhibited, in which a highly active minute region of the transition metal-containing film, for example, a metal crystal grain boundary or a specific crystal orientation or the like is preferentially converted into an organometallic complex and removed, which causes increased unevenness, so that roughening proceeds. This is because the conversion of the film into the organometallic complex occurs immediately after contact of the complexing gas, so that if the surface of the film coming into contact with the complexing gas happens to be a high active region, the film is immediately converted into the organometallic complex and removed, and if the surface of the film coming into contact with the complexing gas is not the high active region, the organic compound as a component of the complexing gas is separated from the film surface without causing physical adsorption.

Meanwhile, in the etching treatment in the process A, the chemical adsorption layer is formed only during a period in which the substrate temperature is raised to and maintained at the second temperature T₂. In the process of forming the chemical adsorption layer at such a relatively low temperature, the chemical adsorption layer is plane-oriented and grown in a self-assembly manner, whereby the planarization of the surface of the transition metal-containing film after the treatment proceeds. That is, the change from physical adsorption to chemical adsorption rapidly proceeds when the molecules of the complexing gas having a three-dimensional structure are aligned and adsorbed to the film surface in a specific direction. In a state where the degree of activity of the film surface is not high, the complexing gas retained by physical adsorption is stabilized by changing the direction to a specific direction (plane orientation growth) without moving away from the film surface, whereby the influence of the microscopic degree of activity of the film surface can be suppressed from appearing in the etching treatment result.

In any case of the process A and the process B, the fourth temperature T₄ is set to be lower than the decomposition start temperature of a complexing gas molecule and the decomposition start temperature of an organometallic complex molecule, and to be equal to or higher than the diffusion (vaporization) start temperature of the organometallic complex molecule. Strictly speaking, the phenomenon in which the organometallic complex is desorbed from the transition metal-containing film may be volatilization or sublimation or the like, but the distinction of the phenomenon is not important here, so that the phenomenon may be comprehensively expressed as vaporization or diffusion. In the case where a temperature difference between the decomposition start temperature and the diffusion start temperature of the organometallic complex molecule is small and is insufficient for the specifications of the semiconductor manufacturing apparatus 100, for example, the uniformity of a temperature in the plane direction of the upper surface of the stage 4, an existing method for lowering the diffusion start temperature of the organometallic complex molecule, for example, a method for reducing the pressure in the treating chamber 1 in order to widen a mean free path may be applied.

When the process A or the process B is completed, the process proceeds to step S108 to start the cooling of the wafer 2. In step S109, the cooling of the wafer 2 is continued until the control unit 40 detects that the substrate temperature has reached the first temperature T₁ from spectroscopic measurement using the optical fiber 92 or the output of the thermocouple thermometer 71.

In step S108, it is desirable to supply a cooling gas between the stage 4 and the wafer 2. As the cooling gas, for example, He or Ar or the like is suitable, and when the He gas is supplied, cooling can be performed in a short time, whereby processing productivity is enhanced. However, the refrigerant flow path 39 connected to the chiller 38 is provided in the stage 4, whereby the wafer 2 can be cooled even in a state where the cooling gas does not flow as long as the wafer 2 is electrostatically adsorbed onto the stage 4.

When the control unit 40 detects that the temperature of the wafer 2 has reached the first temperature T₁, the process returns to step S101, and the control unit 40 determines whether the processing residual amount has reached 0. When the control unit 40 determines that the processing residual amount has reached 0, the etching treatment of the film to be treated of the wafer 2 is completed. When the control unit 40 determines that the processing residual amount is greater than 0, the process proceeds to step S102 again, and the processing of the process A or the process B is performed.

When the treatment of the wafer 2 is completed, the supply of the He gas supplied from the mass flow controller 50-4 to the clearance between the upper surface of the stage 4 and the back surface of the wafer 2 through the opening of the upper surface of the stage 4 through the supply path of the He gas is stopped according to the command signal from the control unit 40. Furthermore, the valve 52 disposed on a waste gas path communicating between the He gas supply path and the vacuum exhaust pipe 16 is changed from a closed state to an opened state, and the He gas in the clearance is discharged to the outside of the treating chamber 1, so that the pressure in the clearance is made substantially the same as the pressure in the treating chamber 1, and the electrostatic adsorption of the wafer 2 including the removal of static electricity is released. Then, the gate of the base chamber 11 is opened, and the wafer 2 is delivered to the arm tip of the transfer robot which has entered from the vacuum transfer container. When the wafer 2 to be treated next is present, the arm of the transfer robot again holds the untreated wafer 2 and enters. When no wafer 2 to be treated is present, the gate is closed, and the operation of manufacturing the semiconductor device by the semiconductor manufacturing apparatus 100 is stopped.

The second temperature and the fourth temperature set in the process A or the process B may be the same value or different between the processes A and B. Furthermore, when the cycle including the process A or the process B shown in FIG. 2 is repeatedly performed one or more times to etch the film to be treated, the first to fourth temperatures may be the same or different between the cycles. These temperatures are carefully considered in advance before the etching treatment of the wafer 2, and an appropriate temperature range is set for each of the first to fourth temperatures. The control unit 40 reads the information of the set temperature range stored in the storage device, and sets the temperature of each step as one of the conditions of the treatment of the wafer 2 in the process A and the process B of each cycle according to the performance required for the semiconductor manufacturing apparatus 100 and the specification of the target wafer 2.

Next, a semiconductor manufacturing method performed by the semiconductor manufacturing apparatus 100 will be described with specific examples.

First, before the etching treatment (FIG. 2) of the wafer 2 is started, the wafer 2 is adsorbed and held on the stage 4, and then the inside of the treating chamber 1 is decompressed to heat the wafer 2. When the wafer 2 is heated to cause the substrate temperature to rise, a gas (water vapor or the like) and foreign substances adsorbed to the surface of the wafer 2 are desorbed. When the gas component adsorbed to the surface of the wafer 2 is confirmed to be sufficiently desorbed, the heating of the wafer 2 is stopped and the cooling of the wafer 2 is started while the inside of the treating chamber 1 is kept depressurized. In this process, known means may be used for heating and cooling. Known methods such as ashing and cleaning of the surface by plasma formed in the treating chamber 1 may be used for removing foreign substances.

When the control unit 40 detects that the substrate temperature has decreased to reach the predetermined first temperature T₁ or lower, the treatment of the wafer 2 is performed according to the flowchart shown in FIG. 2. Before the start of the treatment, for example, before the wafer 2 is loaded into the treating chamber 1, the control unit 40 selects treating conditions such as the type and flow rate of a gas when treating the transition metal-containing film to be treated of the wafer 2, and the pressure in the treating chamber 1, i.e., a so-called treating recipe. For example, the ID number of each wafer 2 is acquired using an engraved mark or the like of the wafer 2, and data such as a history of treatment of the wafer 2 corresponding to the number, a composition and thickness of a film to be etched, an etching amount (target remaining film thickness and etching depth) of the film to be etched, and a condition of an end point of etching are acquired with reference to data from a production management database through a communication facility such as a network (not shown) connected to the control unit 40.

For example, in the case where the treatment to be performed on the wafer 2 is an etching treatment of removing a lanthanum oxide film having an initial thickness of 0.3 nm smaller than a predetermined threshold value, the ionic radii of lanthanum (3+) and oxygen (2−) are respectively about 1.0 angstroms and about 1.3 angstroms, whereby the treatment is determined to be a treatment of removing lanthanum oxide of almost one atomic or molecular layer. A command signal for adjusting the operation is transmitted from the control unit 40 to each unit constituting the semiconductor manufacturing apparatus 100 so as to perform the treatment of the film according to the flow of the process A which proceeds after “processing residual amount <threshold value” is determined in step S102 in FIG. 2.

Meanwhile, when the treatment to be performed on the wafer 2 is a treatment of removing the lanthanum oxide film of 3 nm exceeding the predetermined threshold value, it is necessary to remove about 10 or more lanthanum oxide layers. In the case of etching, for example, one layer at a time according to the flow of the process A, the flow of the process A is repeated 10 times or more, which may causes reduced productivity. Therefore, first, a treatment of collectively removing a plurality of layers (for example, 5 to 6 layers) and then removing the remaining film layers one by one is performed. Specifically, “the processing residual amount>the threshold value” is determined in step S102, and the process proceeds to step S103B. The film to be treated is treated according to the flow of the process B, and then the flow of the process A is performed at least once.

Steps S103A and S103B, which are the first steps of the process A and the process B, are treatments of forming a physical adsorption layer of the complexing gas on the surface of the transition metal-containing film, and are performed while the wafer 2 is maintained at a temperature equal to or lower than the boiling point of the complexing gas. The details of the complexing gas will be described later, but the complexing gas is a gas (organic gas) containing an organic compound containing a Lewis base as a main active ingredient. For example, when an organic compound having a boiling point of about 200° C. is used as such an organic compound, the treatments are performed in a temperature range of about 180° C. or a maximum temperature of about 200° C.

When salicylaldehyde (boiling point: about 200° C.) is used as a component of the organic gas, the first temperature T₁ is preferably about 100° C. to 180° C., and more preferably in the range of 120° C. to 160° C. When the first temperature T₁ is lower than 100° C., it takes a long time to raise and lower the temperature, which may cause lowered productivity. Meanwhile, when the first temperature T₁ exceeds 180° C., the efficiency of adsorption of salicylaldehyde decreases. This makes it necessary to increase the gas flow rate of salicylaldehyde in order to provide adsorption in a short time, which may cause an increased operation cost.

After the physical adsorption layer is formed on the surface of the transition metal-containing film, the temperature of the wafer 2 is rapidly raised to the second temperature T₂ in steps S104A and S104B, to change the adsorption state of the complexing gas on the surface of the transition metal-containing film from the physical adsorption state to the chemical adsorption state. The temperature rise in the process provides activation energy for causing a change in the adsorption state of the particles of the complexing gas adsorbed to the surface of the film.

The second temperature T₂ is determined in consideration of the influence of both the state of the surface of the transition metal-containing film and the characteristics (reactivity) of the complexing material. For example, when an organic gas for complexation mainly containing salicylaldehyde is supplied to a lanthanum oxide film as a film to be treated, a suitable range of the second temperature T₂ is about 120° C. to 210° C. When the second temperature T₂ is lower than 120° C., the time required for the conversion of the film into the chemical adsorption layer is long, and when the second temperature T₂ exceeds 210° C., the film is converted into an organometallic complex without remaining in a chemical adsorption state, which causes a high possibility that the controllability of the film thickness is deteriorated.

In the case where the etching amount is large, for example, in the case where the lanthanum oxide film having a film thickness exceeding 3 nm is removed by etching, the infrared heating is further continued to raise the temperature to the fourth temperature T₄ while the supply of the complexing gas such as salicylaldehyde is maintained according to the flow of the process B (step S105B). The fourth temperature T₄ is set to a temperature lower than a temperature at which the thermal decomposition of the volatile organometallic complex produced by the reaction between the transition metal element of the transition metal-containing film and the complexing gas or the complexing gas occurs, and equal to or higher than a temperature at which the vaporization of the organometallic complex is started. During a period until the supply of the complexing gas is stopped in step S106B, the temperature of the wafer 2 is maintained at a temperature equal to or higher than the fourth temperature T₄, and the surface of the transition metal-containing film on the upper surface of the wafer 2 is substantially continuously etched.

In the case where the etching amount is small, for example, in the case where a lanthanum oxide film having a film thickness of 0.3 nm is removed by etching, the supply of the complexing gas such as salicylaldehyde is stopped according to the flow of the process A, and the inside of the treating chamber 1 is exhausted to discharge particles which affect the treatment (step S105A). Then, the wafer 2 is heated to the third temperature T₃ (step S106A). When the temperature of the transition metal-containing film is set to the third temperature T₃ and maintained during a predetermined period, the chemical adsorption layer produced on the film surface is converted into an organometallic complex.

The third temperature T₃ is set to a temperature in a range equal to or higher than the second temperature T₂ and lower than the diffusion start temperature of the organometallic complex molecule. The temperature is set within the above-described appropriate temperature range in consideration of the stability of the temperature control of the semiconductor manufacturing apparatus 100, and the temperature measurement accuracy of the substrate temperature, and the like. In the case of the etching treatment using the lanthanum oxide film as the transition metal-containing film and the mixed gas mainly containing salicylaldehyde as the complexing gas, the diffusion start temperature of the organometallic complex molecule is about 320° C., whereby the appropriate temperature range of the third temperature T₃ is 120° C. to 310° C.

After the irradiation of the wafer 2 with the IR light from the IR lamp 62 is continued, and the temperature of the wafer 2 is maintained at the third temperature T₃ set in step S106A during a predetermined period, the irradiation intensity of the IR light is further increased in step S107A to raise the temperature of the wafer 2 to the fourth temperature T₄. When the temperature of the wafer 2 is maintained at the fourth temperature T₄, about one to several layers of the organometallic complex converted from the chemical adsorption layer are volatilized and removed.

When the organometallic complex is removed to expose the transition metal-containing film immediately therebelow or a layer of a silicon compound or the like disposed under the transition metal-containing film, the reaction is terminated. In the case of the treatment using the lanthanum oxide film as the transition metal-containing film and the mixed gas mainly containing salicylaldehyde as the etching organic gas, a suitable range of the fourth temperature T₄ is 310° C. to 390° C. This is because if the fourth temperature T₄ is lower than 310° C., the rate of vaporization is slow, which causes reduced efficiency of the treatment, and conversely, if the fourth temperature T₄ exceeds 390° C., the organometallic complex is highly likely to be decomposed.

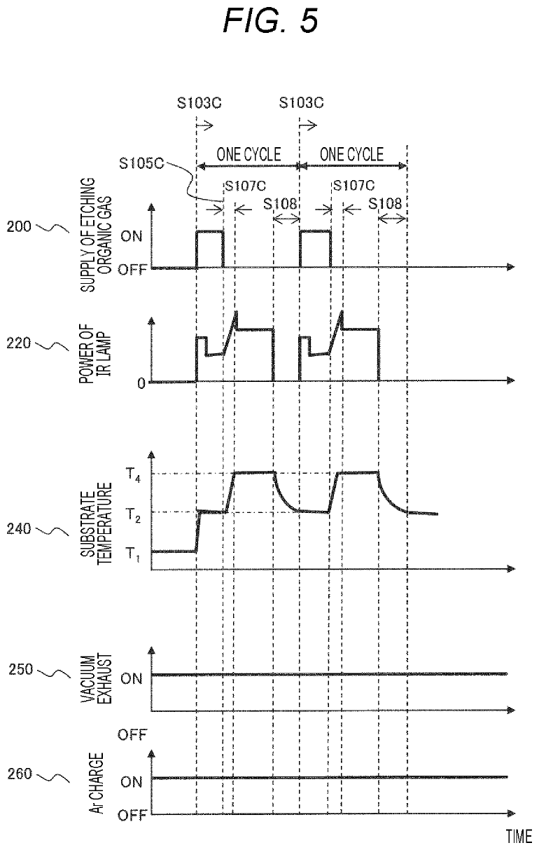

FIG. 5 is a time chart schematically showing the flow of an operation with respect to the transition of time of the etching treatment of the transition metal-containing film to be treated on the wafer performed by the semiconductor manufacturing apparatus, and is identified as an alternative flow of the process A. Therefore, in FIG. 5, the timing corresponding to the step of the flowchart of FIG. 2 is indicated by a reference sign obtained by replacing the reference sign of the corresponding step with C. However, the flow of the operation of the time chart of FIG. 5 is not the same as the flow of the flowchart of FIG. 2, and is indicated as reference information for comparison with the process A.

After the control unit 40 detects that the temperature of the wafer 2 is equal to or lower than the predetermined first temperature T₁, the control unit 40 starts a treatment (step S103C) of supplying an organic gas as a treating gas into the treating chamber 1 to adsorb particles of the organic gas to the surface of the transition metal-containing film to be treated, thereby forming a physical adsorption layer. In the present treatment, after the start of step S103C, power is immediately supplied to the IR lamp 62 to emit IR light, thereby heating the wafer 2 to quickly raise the substrate temperature to the second temperature T₂. As a result, the adsorption state of the particles of the organic gas on the surface of the film to be treated changes from the physical adsorption state to the chemical adsorption state.

The supply of the organic gas to the upper surface of the wafer in the treating chamber 1 is continued while the wafer 2 is maintained at the second temperature T₂ during a predetermined period. Therefore, during this period, a reaction in which the physical adsorption layer of the component of the organic gas is formed on the surface of the transition metal-containing film and a conversion reaction in which the physical adsorption layer is converted into the chemical adsorption layer continuously proceed in parallel.

As described above, the rate at which the organic gas molecules diffuse into the transition metal-containing film via the chemical adsorption layer formed on the surface of the transition metal-containing film is slow, whereby the film thickness of the chemical adsorption layer is saturated with respect to the treatment time. The supply of the organic gas is continued during a predetermined period while the substrate temperature is maintained at the second temperature T₂, and the supply of the organic gas is stopped after the film thickness of the chemical adsorption layer is saturated (S105C).

In the semiconductor manufacturing apparatus 100, the internal pressure of the treating chamber 1 is maintained in a depressurized state by the exhaust mechanism 15 and the pressure regulation mechanism 14 before the supply of the organic gas is started. Therefore, when the supply of the organic gas is stopped, the organic gas chemically adsorbed to the film surface is left, and the organic gas in the non-adsorbed state or the physical adsorption state is wholly exhausted and removed to the outside of the treating chamber 1. It is preferable to continue to supply a small amount of Ar gas into the treating chamber 1 in order to promote the exhaust and removal of the organic gas physically adsorbed to the inner wall or the like of the treating chamber 1 to the outside of the treating chamber 1.

The supply amount of the Ar gas and the pressure in the treating chamber 1 need to be appropriately adjusted according to the compositions of the film to be processed and the etching organic gas. However, in the case where the lanthanum oxide film is etched using the etching organic gas mainly containing salicylaldehyde, the supply amount of Ar is preferably 200 sccm or less, and the pressure in the treating chamber is preferably about 0.5 to 3 Torr. More preferably, the supply amount of Ar is about 100 sccm, and the pressure in the treating chamber is about 1.5 Torr. When the pressure in the treating chamber exceeds 3 Torr, the Ar supply amount increases beyond 200 sccm. The effective concentration of the etching organic gas in the treating chamber 1 decreases, so that the adsorption efficiency to the surface of the film to be processed decreases, which causes a high possibility of a decrease in the etching rate. Meanwhile, when the pressure in the treating chamber is less than 0.5 Torr, the residence time of the etching organic gas in the treating chamber 1 is shortened, so that the use efficiency of the etching organic gas is apt to decrease.

Next, the temperature is raised to the fourth temperature T₄ by infrared heating using the IR lamp 62 (S107C), and is substantially maintained during a predetermined period. In the process of raising the temperature to the fourth temperature T₄ and maintaining the temperature, the conversion from the chemical adsorption layer to the organometallic complex, and the volatilization and removal of the organometallic complex proceed.

When the volatilization and removal of the organometallic complex are completed to expose the transition metal-containing film immediately therebelow or a layer of a silicon compound or the like disposed under the transition metal-containing film, etching for one cycle is completed. Then, by stopping infrared heating using the IR lamp 62, the temperature starts to decrease due to heat dissipation from the wafer 2. When the substrate temperature reaches the second temperature T₂ or lower (S108), the treatment for one cycle is completed.

Then, etching with a predetermined film thickness can be achieved by repeating the second and subsequent cycle treatment starting from step S103C. As compared with the flow of the process A shown in FIG. 4, the temperature hierarchy for the third temperature T₃ is reduced. In particular, the time per cycle can be shortened by narrowing the temperature width of step S108 (cooling step), which is time-consuming, from (T₄−T₁) to (T₄−T₂). By reducing the temperature hierarchy applied to the third temperature T₃, roughness may occur in the etched surface as compared with the flow of the process A, but it is possible to suppress the roughness to a practically acceptable level.

The flow of the operation of the timing chart of FIG. 5 can also be combined with the flow of the timing chart of FIG. 3 or 4. For example, the period in which the temperature is maintained at the third temperature T₃ in the process A may be eliminated, and the temperature may be immediately raised to the fourth temperature T₄ after the supply of the complexing gas is stopped and the excess complexing gas is exhausted from the treating chamber 1. In the process A and the process B, as in the operation of the timing chart of FIG. 5, the temperature after cooling (step S109) may be kept at the second temperature T₂.

Subsequently, suitable components of the etching organic gas will be described.

The main active component of the etching organic gas is an organic compound capable of forming at least one bidentate coordination bonds to a transition metal atom, i.e., a so-called multidentate ligand molecule. The organic compound does not contain halogen, and has any one of the following molecular structural formulae (1) to (3). The organic compound to be used as the etching organic gas may be one kind or a mixture of a plurality of kinds of organic compounds, and these organic compounds are dissolved in an appropriate diluent as necessary to obtain the chemical liquid 44. By dissolving the organic gas in the diluent, the diluent promotes the vaporization of a component represented by the following molecular structural formula, and the vaporized diluent functions as a carrier gas, whereby the organic gas can be smoothly supplied.

The molecular structural formula (1) is a molecular structure shown by (Chemical Formula 1). The molecular structural formula (1) represents an aromatic compound having a benzene ring or the like, in which at least one carbonyl group is bonded to an aromatic ring, and the aromatic compound has an OH group, an OCH₃ group, an NH₂ group, or an N(CH₃)₂ group or the like which is a substituent (Y—X) having Lewis basicity on a carbon atom adjacently connected to a carbon atom on the aromatic ring to which the carbonyl group is bonded. As the carbonyl group bonded to the aromatic ring, a compound in which not OH or NH₂ but H or CH₃ is bonded to the position of Z is suitable.

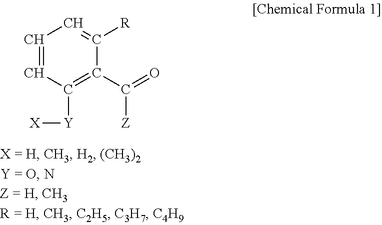

The molecular structural formula (2) is a molecular structure shown by (Chemical Formula 2), and represents a compound having at least one N (nitrogen atom) having Lewis basicity in an aromatic ring, in which a substituent (C═R2) having a C═C bond or a C═O bond is bonded to a carbon atom connected adjacent to the N atom.

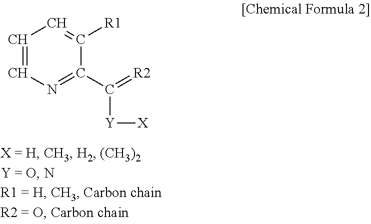

The molecular structural formula (3) represents an aliphatic triamine (n=1), an aliphatic tetraamine (n=2), and an aliphatic pentaamine (n=3) exemplified by (Chemical Formula 3), and represents a compound having a C2 carbon chain between any two N atoms.

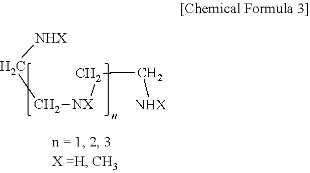

In the molecular structure shown by (Chemical Formula 1), at least one carbonyl group is bonded to a benzene ring, and an atom (Y) having an unshared electron pair is bonded at a position three atoms away from a carbon atom of the carbonyl group. In (Chemical Formula 1), O or N is exemplified as an atom having a Lewis basic unshared electron pair. It is also possible to replace the atom (Y) with an atom having another unshared electron pair such as S or P, but in that case, it is necessary to adjust the process while noting that the diffusion start temperature of the corresponding organometallic complex rises.

In the molecular structure shown by (Chemical Formula 1), H or CH₃ having no unshared electron pair is bonded to the carbonyl group. When O or N having an unshared electron pair is bonded to the carbonyl group, for example, in the case of Z═OH, the boiling point is high, which causes a strong tendency that the supply of the etching organic gas is difficult. In (Chemical Formula 1), salicylaldehyde is obtained in the case of X═H, Y═O, Z═H, and R═H.

In salicylaldehyde, two coordinate bonds are produced in such a manner that an atom (Y), that is, an unshared electron pair of O and an unshared electron pair of O of a carbonyl group are donated to a transition metal element to form an organometallic complex. The coordinate bond is an electron-donating +back-donating type strong bond and forms the bond at two positions, so that the salicylaldehyde metal complex to be obtained becomes a thermally stable complex compound. For example, there is one bond in an acetate of a transition metal or a formate of a transition metal obtained by the reaction between acetic acid or formic acid and a transition metal element as exemplified in the prior art. By bonding by two coordinate bonds, the organometallic complex intermediately produced using the etching organic gas exemplified in the present Example is significantly improved in thermal stability as compared with these carboxylates.

Furthermore, in the case of salicylaldehyde, the OH group (substituent (Y—X)) at a position three atoms away from the carbon atom of the carbonyl group is a substituent which exhibits Broensted acidity, but is partially neutralized in the molecule due to the electron-withdrawing property of the carbonyl group and the Lewis basicity of the O atom of the carbonyl group. When the molecular structure has a polar group, an intermolecular attractive force generally increases, but the influence can be suppressed by partial charge neutralization in the molecule.

In the molecular structure shown by (Chemical Formula 1), a benzene ring, which is a partial molecular structure responsible for the aromaticity thereof, also increases the thermal stability of the intermediately produced organometallic complex. It is also possible to substitute the benzene ring with another aromatic structure such as a naphthalene ring or a tropolone ring, but when the benzene ring is substituted with another aromatic structure, it is necessary to adjust the process while noting that the diffusion start temperature of the corresponding organometallic complex rises.

In the molecular structure shown by (Chemical Formula 2), a side chain is bonded to an adjacent carbon atom of the N atom of the pyridine ring, and C═C (carbon-carbon double bond) or C═O (carbon-oxygen double bond) and an atom (Y) having an unshared electron pair exhibiting Lewis basicity are bonded to the side chain. In (Chemical Formula 2), O or N is exemplified as an atom (Y) having a Lewis basic unshared electron pair.

When the side chain is a carbon-carbon double bond, it may be linked to a carbon chain (R1) extending from an adjacent carbon atom two away the N atom of the pyridine ring. Examples in which the side chain is linked to carbon extending from the adjacent carbon atom two away the N atom of the pyridine ring by the carbon-carbon double bond include quinolinol of X═H, Y═O, and R1 or R2=a benzene ring. In quinolinol, two coordinate bonds are produced in such a manner that an unshared electron pair of O as an atom (Y) and an unshared electron pair of N of a pyridine ring are donated to a transition metal element to form a quinolinol metal complex.

As in the case of the molecular structural formula (1), the coordination bond is an electron-donating+back-donating type strong bond, and the bond is formed at two positions, so that the resulting organometallic complex is a thermally stable complex compound. In the case of quinolinol, the OH group (substituent (Y—X)) at a position 3 atoms away from the N atom of the pyridine ring is a substituent exhibiting Broensted acidity, but is partially neutralized in the molecule by the Lewis basicity of the N atom of the pyridine ring, so that the load on an etching organic gas feeder 47 and the control unit 40 may be reduced through the suppression of the attractive force between the quinolinol molecules, that is, the increase in the volatility of quinolinol, and furthermore the heating of the etching gas supply pipe may be omitted.

In the molecular structure shown by (Chemical Formula 2), the case of X═H, Y═O, R1=H, and R2=O represents picolinic acid. In picolinic acid, two coordinate bonds are produced in such a manner that an unshared electron pair of O which is an atom (Y) and an unshared electron pair of N of a pyridine ring are donated to a transition metal element to form an organometallic complex. Therefore, the resulting picolinate metal complex is a thermally stable complex compound. As in the case of quinolinol, an OH group at a position three atoms away from the N atom of the pyridine ring is a substituent exhibiting Broensted acidity, but picolinic acid is also partially neutralized in the molecule by the Lewis basicity of the N atom of the pyridine ring.

In (Chemical Formula 2), the example in which the pyridine ring is used as the aromatic ring structure exhibiting Lewis basicity is shown, but a pyrrole ring, a pyrazole ring, an imidazole ring, a furan ring, an oxazole ring, an indole ring, a quinoline ring, or a coumarin ring or the like can be used instead of the pyridine ring. However, it is necessary to note that the organic materials having these alternative structures are generally more expensive than materials having a pyridine ring structure in many cases.

The molecular structure shown by (Chemical Formula 3) is an aliphatic polyfunctional amine, and more specifically, a trimer, a tetramer, or a pentamer of ethyleneimine (CH₂—CH₂—NX—), and a derivative thereof. Ethyleneimine has a structure in which an N atom having an unshared electron pair exhibiting Lewis basicity is bonded to both sides of a C2 chain, and in the molecular structure shown by (Chemical Formula 3), either H or CH₃ is bonded to the N atom. An organometallic complex is formed by producing a coordination bond in such a manner that an unshared electron pair on an N atom on each of both sides of an ethyleneimine C2 chain is donated to a transition metal element. The molecular structure shown by (Chemical Formula 3) does not have a heat-resistant structure like an aromatic ring, but is bonded to a transition metal element by at least three electron-donating +back-donating strong bonds, whereby a thermally stable complex compound is obtained.

### REFERENCE SIGNS LIST

1 treating chamber
2 wafer
3 discharge region
4 wafer stage
5 shower plate
6 top plate
11 base chamber
12 quartz chamber
14 pressure regulation mechanism
15 exhaust mechanism
16 vacuum exhaust pipe
17 gas dispersion plate
20 radio frequency power supply
22 matching device
25 radio frequency cut filter
30 electrostatic adsorption electrode
31 DC power supply
34 ICP coil
38 chiller
39 refrigerant flow path
40 control unit
41 calculation unit
44 chemical liquid
45 tank
46 heater
47 complexing gas feeder
50 mass flow controller
51 integrated mass flow controller control unit
52,53,54 valve
60 container
62 IR lamp
63 reflector
64 IR lamp power supply
70 thermocouple
71 thermocouple thermometer
74 IR light transmissive window
75 gas flow path
78 slit plate
81 O-ring
92 optical fiber
93 external IR light source
94 optical path switch
95 light splitter
96 spectroscope
97 detector
98 optical multiplexer
100 semiconductor manufacturing apparatus

1. A semiconductor manufacturing method using a semiconductor manufacturing apparatus including a treating chamber,
the method comprising:
a first process of supplying a complexing gas into the treating chamber in which a wafer having a surface having a transition metal-containing film formed thereon is placed, to adsorb an organic compound as a component of the complexing gas to the transition metal-containing film, the transition metal-containing film containing a transition metal element; and
a second process of heating the wafer in which the organic compound is adsorbed to the transition metal-containing film, to react the organic compound with the transition metal element, thereby converting the organic compound into an organometallic complex, and desorbing the organometallic complex,
wherein the organic compound has Lewis basicity, and is a multidentate ligand molecule capable of forming a bidentate or more coordination bond with the transition metal element.

2. The semiconductor manufacturing method according to claim 1,
wherein:
the complexing gas is supplied into the treating chamber through the first process;
the first process includes a first period in which the wafer is maintained at a first temperature and the complexing gas is supplied, and a second period in which the wafer is heated and the complexing gas is supplied while the wafer is maintained at a second temperature higher than the first temperature; and
the first temperature in the first period is set so that a physical adsorption layer is formed on a surface of the transition metal-containing film of the organic compound, and the second temperature in the second period is set so that an adsorption state of the organic compound to the transition metal-containing film changes from a physical adsorption state to a chemical adsorption state.

3. The semiconductor manufacturing method according to claim 1, wherein:
in the first process, as the supply of the complexing gas into the treating chamber is started, the wafer is heated, and the supply of the complexing gas is continued while the wafer is maintained at a second temperature; and
the second temperature is set so that a reaction in which a physical adsorption layer is formed on a surface of the transition metal-containing film and a conversion reaction in which the physical adsorption layer is converted into a chemical adsorption layer are generated in parallel.

4. The semiconductor manufacturing method according to claim 1, wherein:
the complexing gas is supplied into the treating chamber through the first process and the second process;
in the second process, the wafer is heated and maintained at a fourth temperature and
the fourth temperature is set to a temperature lower than a temperature at which thermal decomposition of the organic compound occurs and a temperature at which thermal decomposition of the organometallic complex occurs, and equal to or higher than a temperature at which the organometallic complex is vaporized.

5. The semiconductor manufacturing method according to claim 1, wherein an organic compound not chemically adsorbed to the transition metal-containing film is exhausted from the treating chamber after completion of the first process, and the second process is then started.

6. The semiconductor manufacturing method according to claim 5, wherein:
the second process includes a third period in which the wafer is heated and maintained at a third temperature and a fourth period in which the wafer is heated and maintained at a fourth temperature higher than the third temperature;
the third temperature in the third period is set to a temperature equal to or higher than the temperature of the wafer in the first process and lower than a temperature at which the organometallic complex is vaporized; and
the fourth temperature in the fourth period is set to a temperature lower than a temperature at which thermal decomposition of the organic compound occurs and a temperature at which thermal decomposition of the organometallic complex occurs and equal to or higher than a temperature at which the organometallic complex is vaporized.

7. The semiconductor manufacturing method according to claim 5, wherein:
in the second process, the wafer is heated and maintained at a fourth temperature; and
the fourth temperature is set to a temperature lower than a temperature at which thermal decomposition of the organic compound occurs and a temperature at which thermal decomposition of the organometallic complex occurs, and equal to or higher than a temperature at which the organometallic complex is vaporized.

8. The semiconductor manufacturing method according to claim 1, wherein the organic compound is an aromatic compound to which a carbonyl group is bonded, and is an organic compound in which a carbon atom on an aromatic ring adjacent to a carbon atom on the aromatic ring to which the carbonyl group is bonded has a substituent having Lewis basicity.

9. The semiconductor manufacturing method according to claim 8, wherein the organic compound has a molecular structure represented by (Chemical Formula 1), 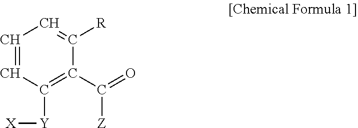
wherein:
X is any one of H, CH₃, H₂, and (CH₃)₂;
Y is O or N;
Z is H or CH₃; and
R is any one of H, CH₃, CH₂H₅, C₃H₇, and C₄H₉.

10. The semiconductor manufacturing method according to claim 1, wherein:
the organic compound is an aromatic compound having a nitrogen atom having Lewis basicity on an aromatic ring; and
a substituent having a C═C bond or a C═O bond is bonded to a carbon atom adjacent to the nitrogen atom.

11. The semiconductor manufacturing method according to claim 10, wherein the organic compound has a molecular structure represented by (Chemical Formula 2), 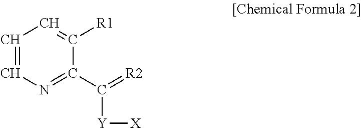
wherein:
X is any one of H, CH₃, H₂, and (CH₃)₂;
Y is O or N;
R1 is any one of H, CH₃ and a carbon chain; and
R2 is O or a carbon chain.

12. The semiconductor manufacturing method according to claim 1, wherein the organic compound is any one of an aliphatic triamine, an aliphatic tetraamine, and an aliphatic pentaamine.

13. A semiconductor manufacturing apparatus comprising:
a chamber in which a treating chamber is provided;
a wafer stage which is disposed in the treating chamber and on which a wafer having a surface having a transition metal-containing film formed thereon is placed, the transition metal-containing film containing a transition metal element;
a complexing gas feeder which includes a tank storing a chemical liquid containing an organic compound as a component, and supplies an organic gas obtained by vaporizing the chemical liquid to the treating chamber as a complexing gas;
a heater heating the wafer; and
a control unit,
wherein:
the control unit executes a first process of supplying the complexing gas from the complexing gas feeder into the treating chamber in which the wafer is placed, to adsorb an organic compound as a component of the complexing gas to the transition metal-containing film, and a second process of causing the heater to heat the wafer in which the organic compound is adsorbed to the transition metal-containing film to react the organic compound with the transition metal element, thereby converting the organic compound into an organometallic complex, and desorbing the organometallic complex; and
the organic compound has Lewis basicity, and is a multidentate ligand molecule capable of forming a bidentate or more coordination bond with the transition metal element.

14. The semiconductor manufacturing apparatus according to claim 13,
wherein:
the control unit supplies the complexing gas from the complexing gas feeder into the treating chamber through the first process and the second process, and causes the heater to heat the wafer to maintain the wafer at a fourth temperature in the second process; and
the fourth temperature is set to a temperature lower than a temperature at which thermal decomposition of the organic compound occurs and a temperature at which thermal decomposition of the organometallic complex occurs, and equal to or higher than a temperature at which the organometallic complex is vaporized.

15. The semiconductor manufacturing apparatus according to claim 13, further comprising an exhaust mechanism exhausting the treating chamber,
wherein the control unit stops supply of the complexing gas by the complexing gas feeder while continuing exhaust of the treating chamber by the exhaust mechanism after completion of the irst process, to exhaust an organic compound not chemically adsorbed to the transition metal-containing film from the treating chamber.

16. The semiconductor manufacturing apparatus according to claim 15, wherein:
the control unit causes the heater to heat the wafer to maintain the wafer at a fourth temperature in the second process, and
the fourth temperature is set to a temperature lower than a temperature at which thermal decomposition of the organic compound occurs and a temperature at which thermal decomposition of the organometallic complex occurs, and equal to or higher than a temperature at which the organometallic complex is vaporized.

17. The semiconductor manufacturing apparatus according to claim 13, further comprising:
a thermometer detecting a temperature of the wafer stage; and
a detector irradiating the wafer with infrared light to detect a spectral intensity of the infrared light absorbed and reflected by the wafer,
wherein the control unit controls the heater based on a temperature of the wafer estimated from the temperature of the wafer stage detected by the thermometer or detected by the detector.
